(19) United States
(12) Patent Application Publication
(10) Pub. No.: US 2025/0301561 A1
(43) Pub. Date: Sep. 25, 2025

(54) COOLER AND SEMICONDUCTOR MODULE

(71) Applicant: FUJI ELECTRIC CO., LTD., Kawasaki-shi (JP)

(72) Inventor: Yoshihiro TATEISHI, Kawasaki-shi (JP)

(73) Assignee: FUJI ELECTRIC CO., LTD., Kawasaki-shi (JP)

(21) Appl. No.: 19/065,057

(22) Filed: Feb. 27, 2025

(30) Foreign Application Priority Data
Mar. 22, 2024 (JP) 2024-045842

(51) Int. Cl. H05K 1/02

(52) U.S. Cl. CPC H05K 1/0203

(57) ABSTRACT

A cooler includes a plurality of protrusions disposed on a top plate surface of a top plate, protruding in a depth direction toward a bottom plate surface of a bottom plate in a flow path of refrigerant formed between the top plate surface and the bottom plate surface, and including first and second protrusions that are spaced apart from each other in a flowing direction in which the refrigerant flows in the flow path, a frame connecting the top plate to the bottom plate and having wall surfaces surrounding the plurality of protrusions, and a wall disposed on the bottom plate surface and protruding in the depth direction, between the first and second protrusions. The wall is respectively connected to a pair of the wall surfaces at opposite ends thereof in a width direction orthogonal to the flowing direction. The wall is spaced apart from the top plate surface.

### CROSS-REFERENCE TO RELATED APPLICATION

This application is based upon and claims the benefit of priority to Japanese Patent Application No. 2024-045842, filed on Mar. 22, 2024, the entire contents of which are incorporated herein by reference.

### BACKGROUND OF THE INVENTION

### 1. Technical Field

The present invention relates to a cooler and a semiconductor module.

### 2. Description of the Related Art

Some coolers for cooling electronic components such as semiconductor devices are provided with a refrigerant flow path configured to allow refrigerant to circulate therethrough. Some coolers of this type improve cooling efficiency on the downstream side of a throttle portion by partially providing the throttle portion with a reduced flow path width of the refrigerant flow path (for example, JP 2009-182313 A).

### SUMMARY OF THE INVENTION

In the cooler described above, cooling efficiency on the downstream side of a refrigerant flow path deteriorates due to the temperature rise of refrigerant flowing through a portion of the refrigerant flow path, in which the portion is close in distance from the surface on which an electronic component is disposed.

The present invention has been made in view of such a point, and an object thereof is to improve cooling performance of a cooler.

A cooler according to one aspect of the present invention includes: a top plate portion forming a first surface of a flow path of refrigerant; a bottom plate portion forming a second surface facing the first surface in the flow path of the refrigerant; a plurality of protrusion portions disposed in the flow path of the refrigerant, the protrusion portions protruding in a direction oriented from the first surface toward the second surface; a frame portion connecting the first surface to the second surface in the flow path of the refrigerant, the frame portion forming wall surfaces surrounding the plurality of protrusion portions; and a wall portion protruding in a direction oriented from the second surface toward the first surface, the wall portion being located between a first protrusion portion and a second protrusion portion among the plurality of protrusion portions, the first protrusion portion and the second protrusion portion being spaced apart from each other by a predetermined distance in a flowing direction of the refrigerant in the flow path of the refrigerant. The wall portion is respectively connected to a pair of the wall surfaces located at ends in a flow path width direction orthogonal to the flowing direction of the refrigerant in plan view of the second surface, and the wall portion has a section spaced apart from the first surface when viewed in the flow path width direction.

According to the present invention, cooling performance of a cooler can be improved.

### BRIEF DESCRIPTION OF THE DRAWINGS

FIGS. 1A and 1B are perspective views illustrating an external configuration example of a cooler according to a first embodiment;

FIG. 2 is a plan view in which a part of the cooler is omitted;

FIG. 3 is a side cross-sectional view of the cooler taken along line A-A′ in FIG. 2;

FIG. 4 is a side cross-sectional view of the cooler taken along line B-B′ in FIG. 2;

FIG. 5 is a diagram supplementing a shape of a wall portion of the cooler;

FIG. 6 is a partial cross-sectional view illustrating a flow of refrigerant around the wall portion;

FIG. 7 is a partial plan view illustrating a flow of refrigerant around the wall portion;

FIG. 8 is a graph illustrating a relationship between a height of the wall portion and cooling performance;

FIG. 9 is a graph illustrating a relationship between a depth of a notched section and cooling performance;

FIG. 10 is a partial plan view illustrating a shape of a wall portion in a cooler according to a second embodiment;

FIG. 11 is a graph illustrating a relationship between a length of a notched section of a wall portion and cooling performance;

FIG. 12 is a perspective view illustrating a modification of the shape of the notched section provided in the wall portion;

FIGS. 13A and 13B are partial cross-sectional views illustrating a modification of a height of the wall portion;

FIG. 14 is a partial plan view illustrating a modification of a shape of a wall surface on the upstream side of the wall portion;

FIG. 15 is a partial side cross-sectional view illustrating a modification of the method of providing the wall portion;

FIGS. 16A and 16B are side cross-sectional views illustrating a modification of a configuration of the cooler;

FIG. 17 is a plan view illustrating a configuration example of a semiconductor module to which the cooler according to the embodiment is attached;

FIG. 18 is an equivalent circuit diagram of an exemplary power conversion circuit formed in the semiconductor module; and

FIG. 19 is a plan view illustrating an example of arrangement of wall portions of the cooler.

### DETAILED DESCRIPTION

Hereinafter, embodiments of the present invention will be described in detail with reference to the drawings. It is noted that the X-axis, the Y-axis, and the Z-axis in each of the drawings to be referred to are illustrated for the purpose of defining a plane and a direction in the exemplified cooler or the like. The X, Y, and Z axes are orthogonal to each other and form a right-handed system. In the following description, a direction parallel to the X-axis is referred to as an X direction, a direction parallel to the Y-axis is referred to as a Y direction, and a direction parallel to the Z-axis is referred to as a Z direction. In addition, in a case where each of the X direction, the Y direction, and the Z direction is associated with a direction of an arrow (positive or negative) of the X-axis, the Y-axis, and the Z-axis illustrated, a “positive side” or a “negative side” is added.

In the present specification, the Z direction may be referred to as a vertical direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “a member B is disposed on a member A”, the member B is disposed on the positive side in the Z direction as viewed from the member A. Further, when the “upper surface of the member A” is described, the surface is positioned at the end of the member A on the positive side in the Z direction and faces the positive side in the Z direction. Such directions and surfaces are terms used for convenience of description. Thus, a correspondence relationship with each of the directions of the X-axis, the Y-axis, and the Z-axis may vary depending on a mounting posture of a cooler or the like. For example, a surface of the cooler on which a wiring board and a semiconductor element are disposed is referred to as an upper surface of the cooler in the present specification, but is not limited thereto, and may be referred to as a lower surface, a side surface, or the like of the cooler. In the present specification, the X direction, the Y direction, and the Z direction may be expressed as directions associated with a flow path of refrigerant.

An aspect ratio and a magnitude relationship between the members in each drawing are merely schematically represented, and do not necessarily coincide with a relationship in a cooler or the like actually manufactured. For convenience of description, it is also assumed that the size relationship between the respective members is exaggerated. In addition, some reference numerals in the drawings are underlined to indicate that a part of the components referred to by the reference numerals is a reference numeral that refers to the entirety of the components when the part is referred to by another reference numeral.

In the following description, a detailed description of a configuration, a function, an operation, a manufacturing method, and the like that are the same as or similar to those of the known coolers in the exemplified coolers will be omitted.

### First Embodiment

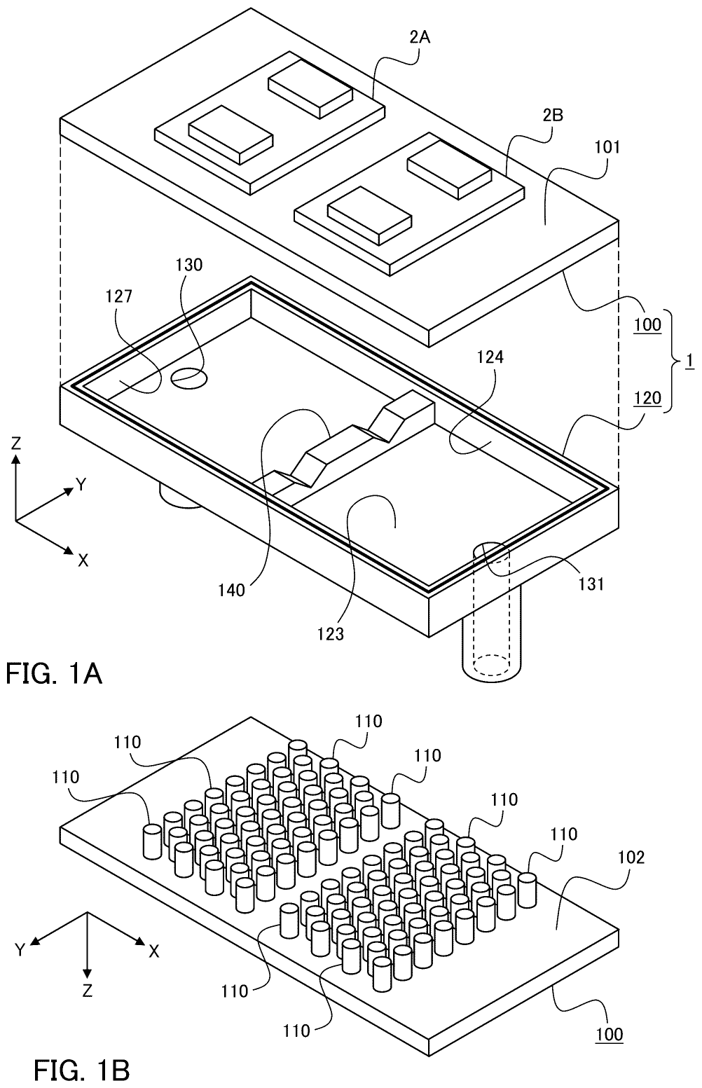

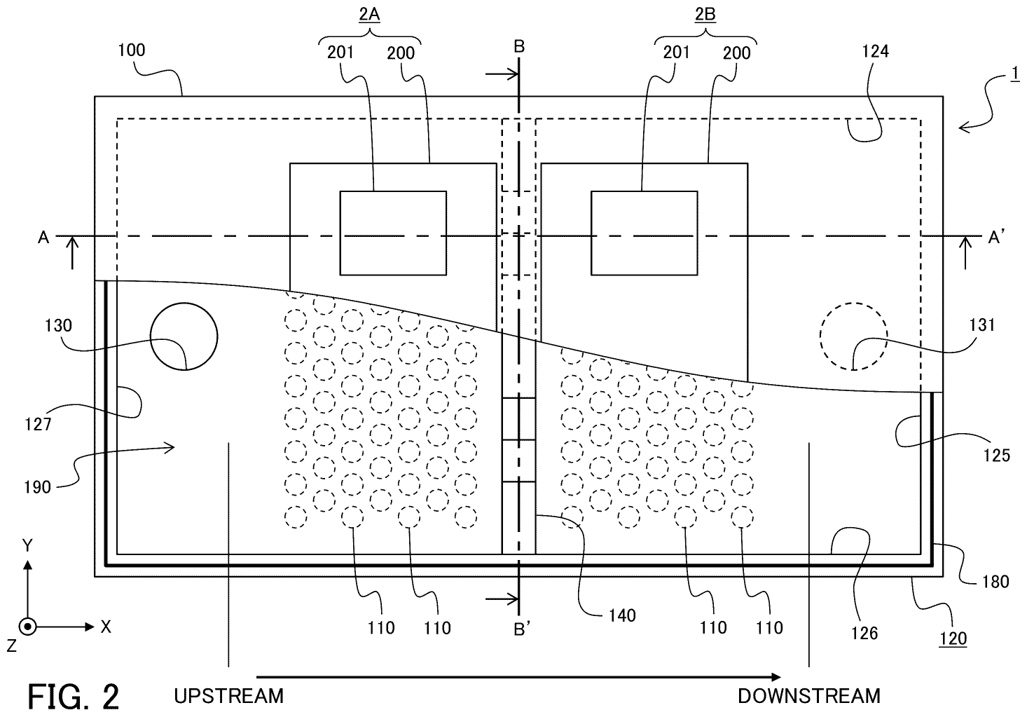

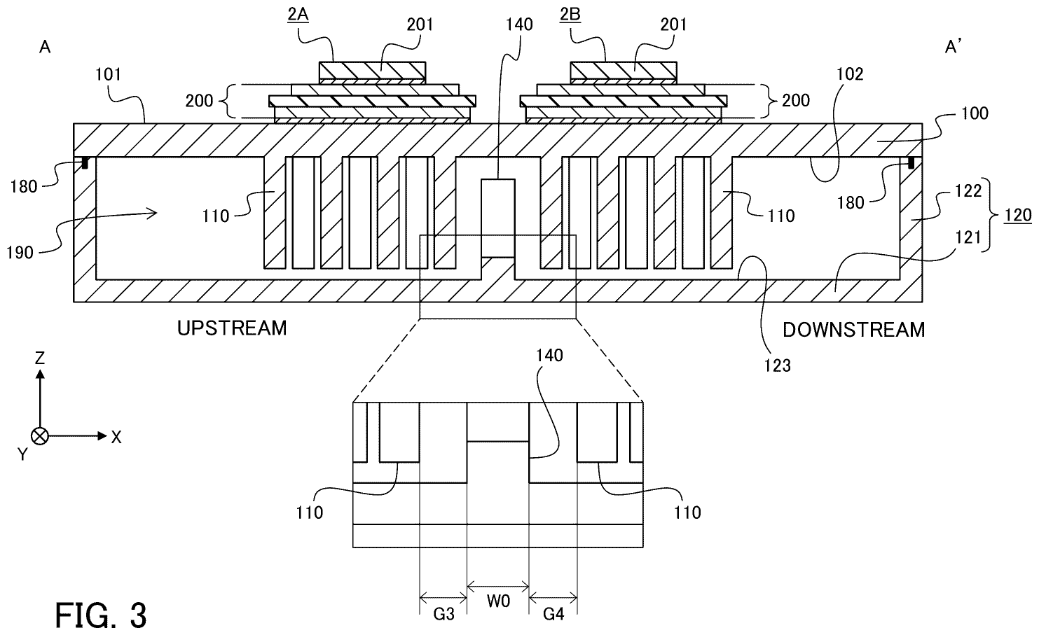

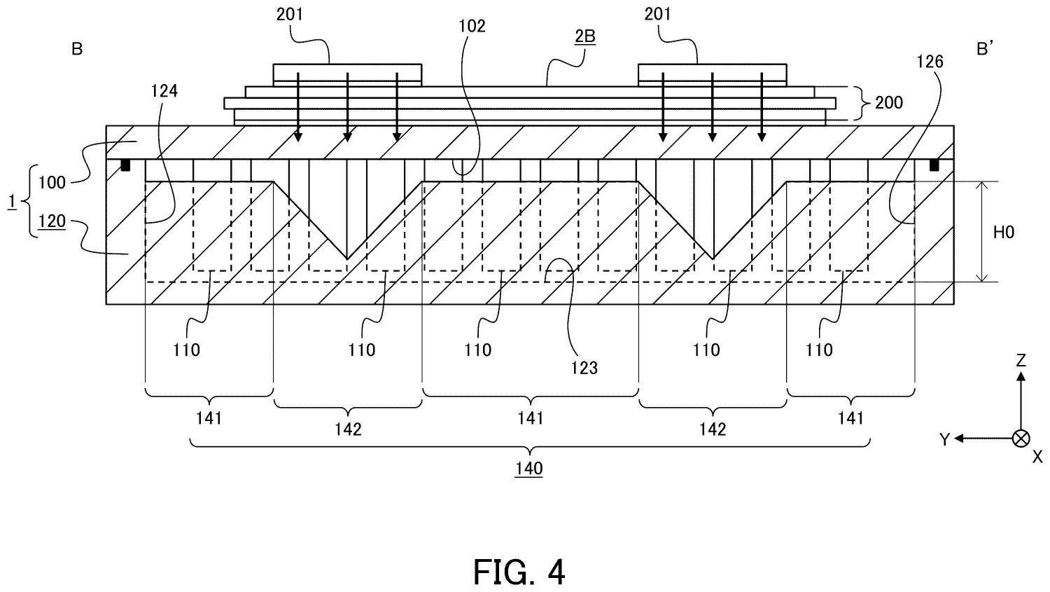

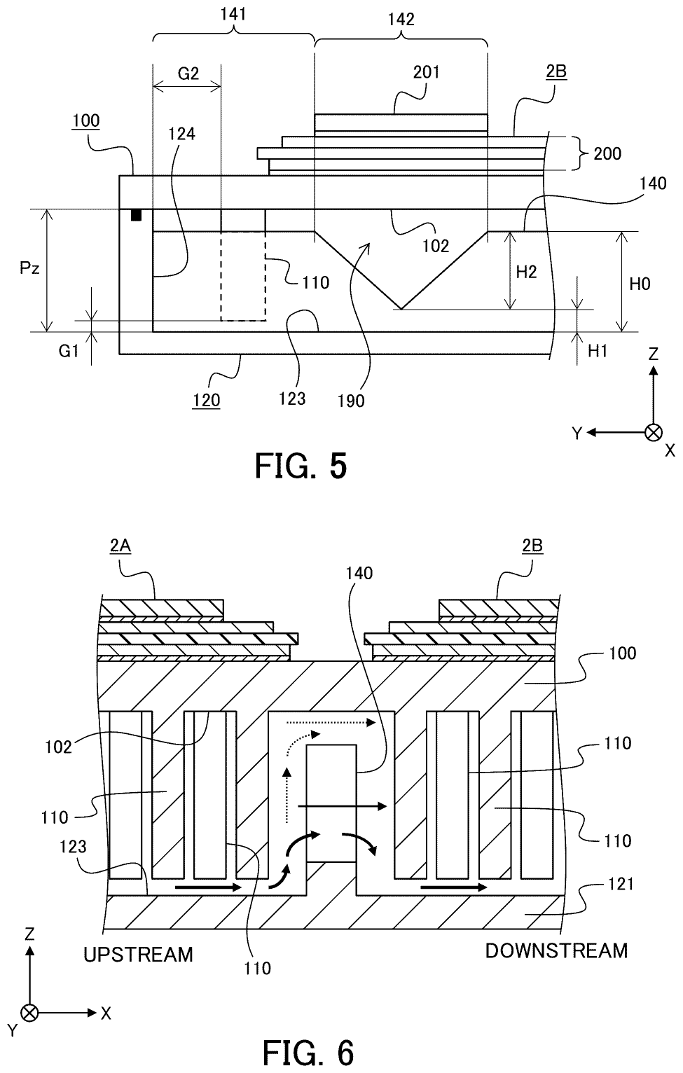

FIGS. 1A and 1B are perspective views illustrating an external configuration example of a cooler according to a first embodiment. FIG. 2 is a plan view in which a part of the cooler is omitted. FIG. 3 is a side cross-sectional view of the cooler taken along line A-A′ in FIG. 2. FIG. 4 is a side cross-sectional view of the cooler taken along line B-B′ in FIG. 2. FIG. 5 is a diagram supplementing a shape of a wall portion of the cooler. The side cross-sectional view of FIG. 3 is a view of a portion of the cooler taken along line A-A′ of FIG. 2, the portion being located above the line A-A′, as viewed from the negative side in the Y direction. The side cross-sectional view of FIG. 4 is a view of a portion of the cooler taken along line B-B′ of FIG. 2, the portion being closer to the left side than the line B-B′, as viewed from the negative side in the X direction. FIG. 5 illustrates a part of the cooler on the YZ plane on the negative side in the X direction with respect to the line B-B′in FIG. 2, and hatching indicating a cross section is omitted.

A cooler 1 illustrated in FIGS. 1A, 1B, and 2 to 4 includes a top plate 100 and a water jacket 120. The top plate 100 and the water jacket 120 are made of a metal or alloy having high thermal conductivity, such as aluminum or copper, and are manufactured by a known method such as casting, pressing, or a method using a 3D printer.

In the top plate 100, the heating elements 2A and 2B are disposed on an upper surface 101, and a plurality of protrusion portions (pin fins) 110 are disposed on a lower surface 102. The illustrated top plate 100 is a plate-shaped member having a rectangular shape in plan view of the upper surface 101, and the two heating elements 2A and 2B are disposed in the longitudinal direction (X direction). The heating elements 2A and 2B may be, for example, those in which a semiconductor element 201 is disposed on the upper surface of a wiring board 200. On the lower surface 102 of the top plate 100, as illustrated in FIG. 1B, a plurality of the protrusion portions 110 are disposed in each of regions where the heating elements 2A and 2B are disposed in plan view of the lower surface 102. The protrusion portions 110 disposed in a first region where the first heating clement 2A is disposed and the protrusion portions 110 disposed in a second region where the second heating element 2B is disposed are separated from each other by a predetermined distance longer than an interval between the protrusion portions 110 in the same region. The shape of each of the protrusion portions 110 is not limited to the illustrated columnar shape. The arrangement pattern of the protrusion portions 110 is not limited to a specific pattern. The top plate 100 is an example of a top plate portion having a top plate surface (first surface) located at a first side of a flow path of the refrigerant 190.

The water jacket 120 is a member that is attached to the lower surface 102 of the top plate 100 so as to form the flow path of the refrigerant 190, and includes a bottom plate portion 121 and a frame portion 122. The bottom plate portion 121 is a flat plate-shaped portion which forms a bottom surface 123 facing the lower surface 102 of the top plate 100 in the flow path of the refrigerant 190 and in which the X direction is a longitudinal direction in plan view of the bottom surface 123. The frame portion 122 is a portion that is connected to the bottom surface 123 and the lower surface 102 of the top plate 100 in the flow path of the refrigerant 190, forms wall surfaces 124 to 127 surrounding the protrusion portions 110 of the top plate 100, and has a quadrangular annular shape in plan view of the bottom surface 123. The bottom plate portion 121 is an example of a bottom plate portion having a bottom plate surface (second surface) that is located at a second side facing the first side (the lower surface 102 of the top plate 100) in the flow path of the refrigerant 190, and the frame portion 122 is an example of a frame portion that is connected to the first surface and the second surface in the flow path of the refrigerant 190 and forms a wall surface surrounding the plurality of protrusion portions 110. A groove for disposing a packing 180 is formed in the upper surface of the frame portion 122. In the illustrated water jacket 120, through holes 130 and 131 that allow the flow path of the refrigerant 190 and the external space to communicate with each other are formed in both ends of the bottom plate portion 121 in the longitudinal direction. The refrigerant having flowed into the flow path of the refrigerant 190 from one through hole (for example, the through hole 130 on the negative side in the X direction) flows in the longitudinal direction (X direction) and flows out from the other through hole (for example, the through hole 131 on the positive side in the X direction). In the cooler 1 according to the present embodiment, heat generated by the heating elements 2A and 2B disposed on upper surface 101 of the top plate 100 is conducted to the protrusion portions 110 of the top plate 100, and heat exchange is performed between the protrusion portions 110 and the refrigerant flowing through the flow path of the refrigerant 190, thereby cooling the heating elements 2A and 2B.

Further, the water jacket 120 of the cooler 1 of the present embodiment has a wall portion 140 protruding from the bottom surface 123. Both ends of the wall portion 140 in the flow path width direction (Y direction) orthogonal to the flowing direction of the refrigerant (X direction) in plan view of the bottom surface 123 are connected to the wall surfaces 124 and 126 of the frame portion 122, respectively. The upper surface of the wall portion 140 is separated from the lower surface 102 of the top plate 100, and has a section 141 having a height H0 and a notched section 142 in which the height from the bottom surface 123 varies in a range of H0 to H1 (<H0) when viewed in the flow path width direction. The notched section 142 of the exemplified wall portion 140 is provided in a V-shape in which the positions of both ends in the flow path width direction substantially coincide with the positions of both ends of the semiconductor element 201 serving as a heat source of each of the heating elements 2A and 2B (refer to FIG. 4), and is the lowest at an intermediate position equidistant from both ends. The water jacket 120 having the wall portion 140 provided with such a notched section 142 can suppress variations in the shape of the notched section 142 when formed by, for example, aluminum casting.

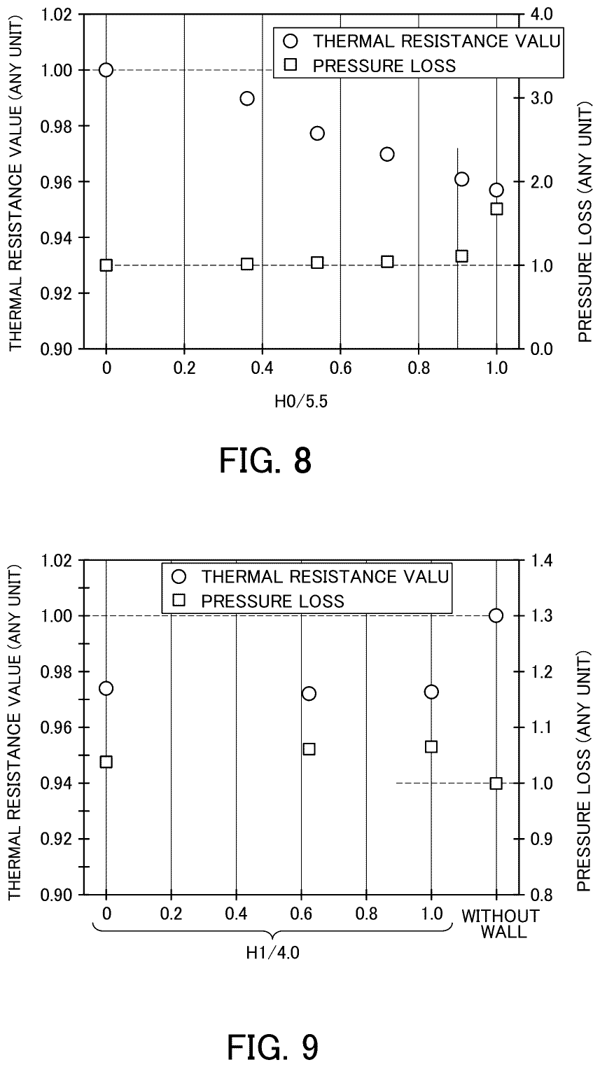

In the cooler 1, as illustrated in FIG. 5, a magnitude relationship between the height H0 of the wall portion 140 and a height (dimension in the Z direction) Pz of the flow path of the refrigerant 190 is Pz>H0, and a difference Pz−H0 is associated with cooling performance to be described later with reference to FIG. 8. A magnitude relationship between the minimum height H1 of the notched section 142 and a distance G1 from the bottom surface 123 to the lower surface of the protrusion portion 110 is H1>G1, and the distance G1 is set based on, for example, the manufacturing tolerance of the cooler 1. The minimum height H1 of the notched section 142 may be a value obtained by subtracting a maximum depth H2 of the notch in the notched section 142 from the height H0 (that is, H1=H0−H2). A distance G2 between the wall surface 124 at the end of the frame portion 122 in the flow path width direction (Y direction) and the protrusion portion 110 closest to the wall surface 124 is also set based on the manufacturing tolerance of the cooler 1.

A thickness (dimension in the flowing direction of the refrigerant (X direction)) W0 of the wall portion 140 illustrated in FIG. 3 may be, for example, within a range of 4 mm to 10 mm, but is not limited to a specific value. A distance G3 between the protrusion portion 110 closest to the wall portion 140 on the upstream side of the wall portion 140 and the wall portion 140 and a distance G4 between the protrusion portion 110 closest to the wall portion 140 on the downstream side of the wall portion 140 and the wall portion 140 are set based on the manufacturing tolerance of the cooler 1, and are not limited to specific values.

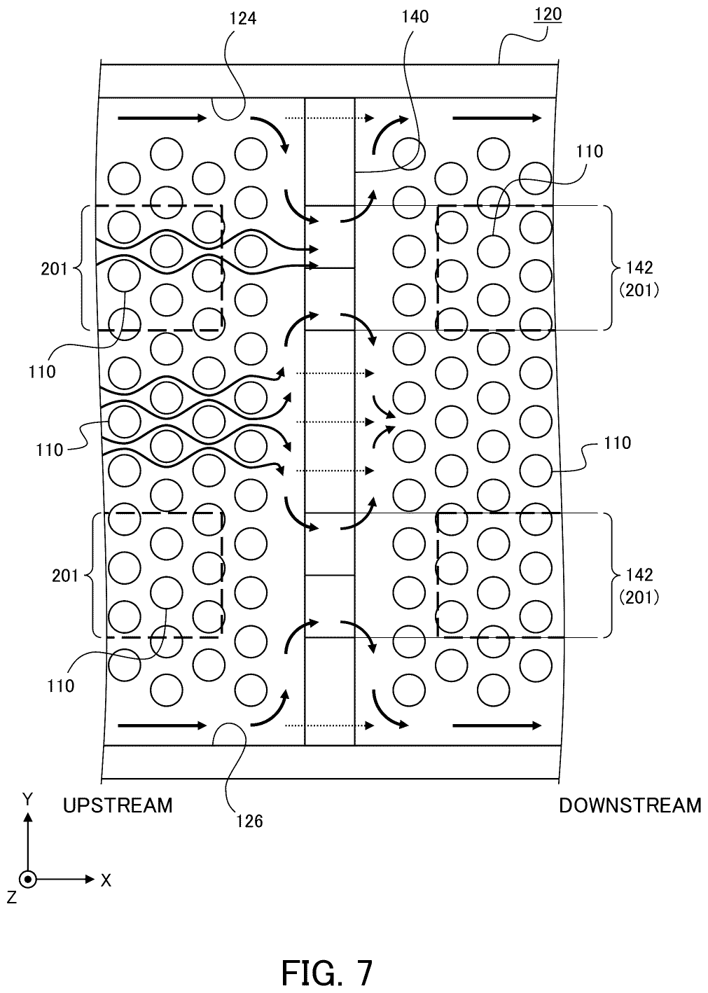

FIG. 6 is a partial cross-sectional view illustrating a flow of refrigerant around the wall portion. FIG. 7 is a partial plan view illustrating a flow of refrigerant around the wall portion. In FIGS. 6 and 7, the flow of the refrigerant is schematically indicated by solid arrows and dotted arrows.

As illustrated in FIG. 7, the refrigerant flowing through the flow path of the refrigerant 190 in the cooler 1 according to the present embodiment exchanges heat with the protrusion portions 110 while repeating flow diversion and joining by the protrusion portions 110. Accordingly, the temperature of the refrigerant flowing through a space between the protrusion portions 110 increases toward the downstream side. When a clearance is provided between the bottom surface 123 of the flow path of the refrigerant 190 and the lower surface of the protrusion portions 110 as illustrated in FIG. 6, a temperature rise of the refrigerant due to heat exchange between the refrigerant flowing along the bottom surface 123 and the protrusion portions 110 is suppressed. Similarly, when a clearance is provided between the wall surfaces 124 and 126 of the flow path of the refrigerant 190 and the protrusion portions 110, a temperature rise of the refrigerant due to heat exchange between the refrigerant flowing along the wall surfaces 124 and 126 and the protrusion portions 110 is suppressed. However, in the conventional cooler 1 not provided with the wall portion 140, the refrigerant flowing along the bottom surface 123 and the wall surfaces 124 and 126 and the refrigerant flowing through a space between the protrusion portions 110 are not agitated, and the refrigerant having a relatively low temperature and flowing along the bottom surface 123 and the wall surfaces 124 and 126 cannot be effectively used for cooling the heating element 2B on the downstream side.

On the other hand, in the cooler 1 of the present embodiment, as illustrated in FIG. 6, the refrigerant flowing along the bottom surface 123 collides with the wall portion 140, so that the refrigerant flows toward the lower surface 102 of the top plate 100 along the wall portion 140. Accordingly, agitation between the refrigerant having a relatively high temperature and flowing through a portion (space between the protrusion portions 110) close to the lower surface 102 of the top plate 100 and the refrigerant having a relatively low temperature and flowing along the bottom surface 123 is promoted. As illustrated in FIG. 7, when the refrigerant flowing along the wall surfaces 124 and 126 collides with the wall portion 140, a flow of the refrigerant toward the notched section 142 along the wall portion 140 is generated. Therefore, agitation between the refrigerant flowing through a space between the protrusion portions 110 (particularly, space between the protrusion portions 110 in an active region overlapping the semiconductor element 201 in plan view) and having a relatively high temperature and the refrigerant flowing along the wall surfaces 124 and 126 and having a relatively low temperature is promoted. Therefore, in the cooler 1 of the present embodiment, the temperature of the refrigerant flowing through a space between the protrusion portions 110 on the downstream side of the wall portion 140 can be lowered as compared with a case in which the wall portion 140 is not provided. When a clearance is provided between the bottom surface 123 and the lower surface of the protrusion portions 110, a flow velocity of the refrigerant flowing along the bottom surface 123 is higher than a flow velocity of the refrigerant flowing through a space between the protrusion portions 110. Similarly, when a clearance is provided between the wall surfaces 124 and 126 and the protrusion portions 110, a flow velocity of the refrigerant flowing along the wall surfaces 124 and 126 is higher than a flow velocity of the refrigerant flowing through a space between the protrusion portions 110. The refrigerant having a flow velocity higher than that of the refrigerant flowing through a space between the protrusion portions 110 collides with the wall portion 140 and flows into the notched section 142, so that a flow velocity of the refrigerant passing through the notched section 142 is improved. Therefore, on the downstream side of the wall portion 140, heat exchange is performed between the protrusion portions 110 and the refrigerant, the temperature rise of which is suppressed by agitation, and the flow velocity of which is improved, thereby improving cooling performance of the cooler.

In particular, the wall portion 140 in the cooler 1 of the present embodiment is different from the throttle portion in the cooler of JP 2009-182313 A, and can promote agitation between the refrigerant having a relatively low temperature and flowing along the bottom surface 123 in the flow path of the refrigerant 190 and the refrigerant having a relatively high temperature and flowing along the lower surface 102 of the top plate 100. Therefore, the cooler 1 of the present embodiment has improved cooling performance as compared with the cooler of JP 2009-182313 A.

FIG. 8 is a graph illustrating a relationship between a height of a wall portion and cooling performance. FIG. 9 is a graph illustrating a relationship between a depth of a notched section and cooling performance. In the graph of FIG. 8, a thermal resistance value on the left vertical axis and a pressure loss on the right vertical axis can be relative values to a thermal resistance value and a pressure loss when H0/5.5=0 on the horizontal axis. In the graph of FIG. 9, a thermal resistance value on the left vertical axis and a pressure loss on the right vertical axis can be relative values to a thermal resistance value and a pressure loss in a cooler in which the wall portion 140 described above is not provided.

The graph of FIG. 8 shows a relationship between a ratio H0/5.5 of the height H0 of the wall portion 140 to the height Pz when the height Pz of the flow path of the refrigerant 190 is set to 5.5 mm and each of the thermal resistance value and the pressure loss. In this example, as illustrated in FIG. 5 and the like, the positions of both ends in the flow path width direction (Y direction) in the notched sections 142 and 143 of the wall portion 140 are made to coincide with the positions of both ends in the width direction of the semiconductor element 201, and the maximum depth H2 of the notch is made constant. The thermal resistance value and the pressure loss when H0/5.5=0 in the graph of FIG. 8 correspond to the thermal resistance value and the pressure loss in the cooler in which the wall portion 140 is not provided. As illustrated in the graph of FIG. 8, the thermal resistance value decreases as the height H0 of the wall portion 140 increases, but the pressure loss increases when the height ratio H0/5.5 is larger than 0.9. That is, when the height ratio H0/5.5 is larger than 0.9, the flow rate of the refrigerant decreases, leading to deterioration in cooling performance. Therefore, the height H0 of the wall portion 140 is preferably set such that the ratio H0/Pz of the height H0 of the wall portion 140 to the height Pz of the flow path of the refrigerant 190 falls within the range of 0.2≤H0/Pz≤0.9. In other words, the height H0 of the wall portion 140 is preferably set to 20% to 90% of the height Pz of the flow path of the refrigerant 190.

The graph of FIG. 9 shows a relationship between the ratio H1/4 of the minimum height H1 of the notched section to the height H0 when the height H0 of the wall portion 140 is set to 4 mm and each of the thermal resistance value and the pressure loss. In this example, the height Pz of the flow path of the refrigerant 190 is set to 5.5 mm, and the positions of both ends in the flow path width direction (Y direction) in the notched section 142 of the wall portion 140 are made to coincide with the positions of both ends in the flow path width direction of the semiconductor element 201. The thermal resistance value and the pressure loss of “no wall portion” in the graph of FIG. 9 are the thermal resistance value and the pressure loss in the cooler in which the wall portion 140 is not provided. As shown in the graph of FIG. 9, the thermal resistance value is a substantially constant value that is smaller than that in the case without a wall portion regardless of the minimum height H1 of the notched section, but as the ratio H1/4 of the height approaches 0, a flow path area of the notched section 142 increases, and the pressure loss decreases. However, a difference from the pressure loss in the case where the wall portion 140 is not provided is, for example, about the same as a difference between the pressure loss in the case of H0/5.5=0 and the pressure loss in the case of 0.2≤H0/5.5≤0.9 in the graph of FIG. 8. Therefore, the minimum height H1 of the notched section of the wall portion 140 can be set such that the ratio H1/H4 of the minimum height H1 to the height H0 of the wall portion 140 falls within the range of 0≤H1/H0≤1. In the case of the wall portion 140 of H1/H0=1, that is, the wall portion 140 having no notched section, as described above with reference to FIG. 8, it is preferable to determine the ratio H0/Pz of the height H0 of the wall portion 140 to the height Pz of the flow path of the refrigerant 190 such that an increase in pressure loss falls within an allowable range.

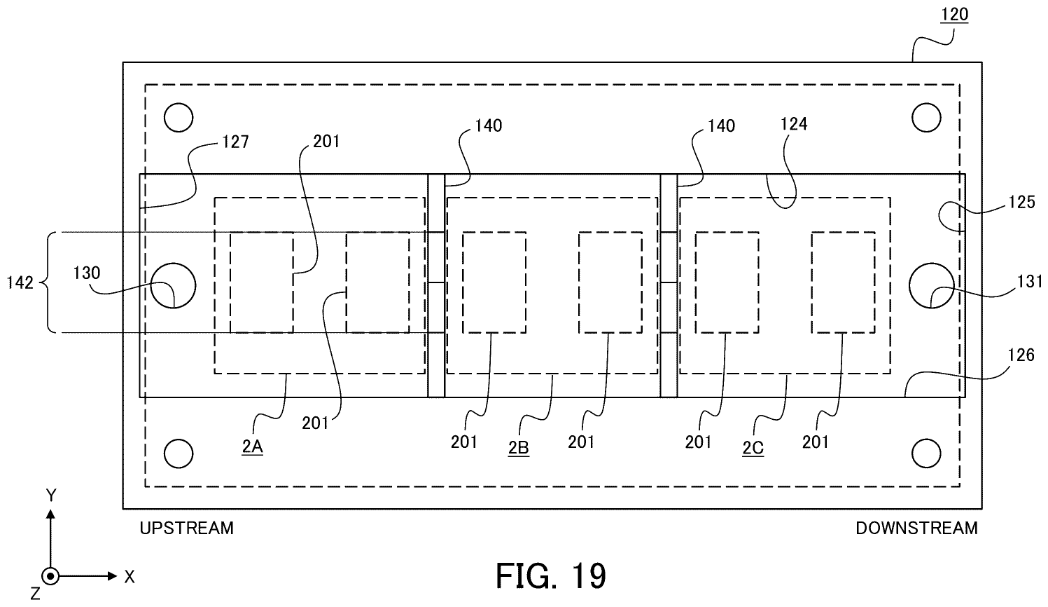

The number and shape of the notched sections 142 in the wall portion 140 in the cooler 1 of the present embodiment can be appropriately changed according to the heating element 2 disposed on the upper surface 101 of the top plate 100. For example, when there is one semiconductor element 201 in the heating element 2 on the downstream side of the wall portion 140, or when two or more semiconductor elements 201 are disposed in the flowing direction of the refrigerant (X direction), one notched section 142 may be provided in the wall portion 140 (refer to FIG. 19). In addition, for example, when the heating element 2 in which three or more semiconductor elements 201 are disposed in the flow path width direction (Y direction) is disposed on the downstream side of the wall portion 140, the wall portion 140 may be provided with the same number of notched sections 142 as the number of semiconductor elements 201. Furthermore, the dimension in the flow path width direction of one notched section 142 may not coincide with the dimension in the flow path width direction of the semiconductor element 201. The shape of the notched section 142 is not limited to the V-shape when viewed from the upstream side as exemplified in FIGS. 4, 5, and the like, and may be, for example, another shape such as a rectangle or a U-shape.

### Second Embodiment

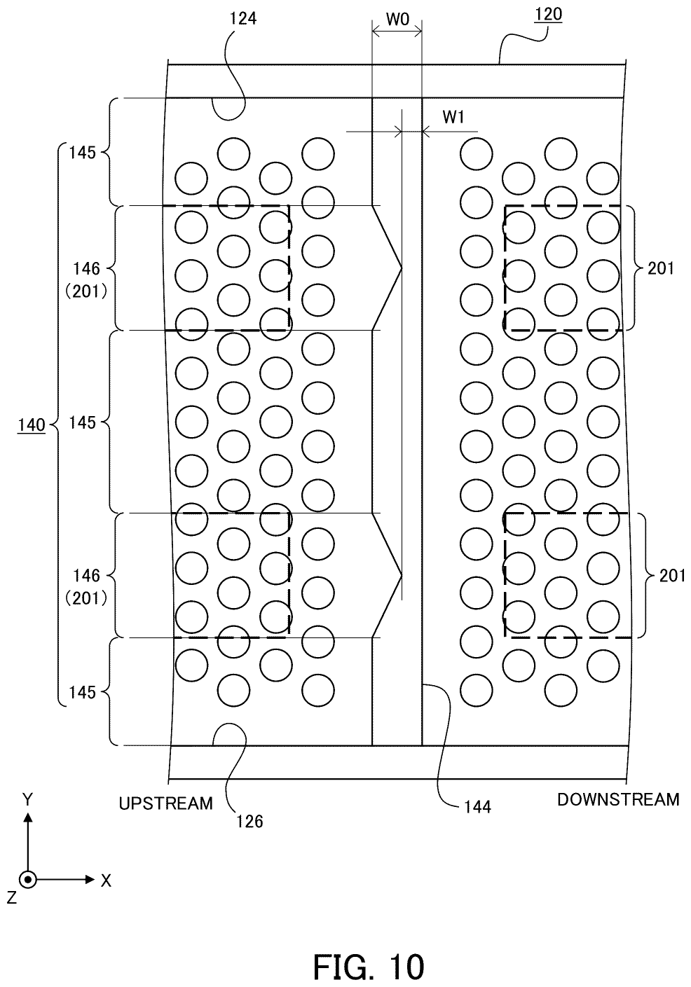

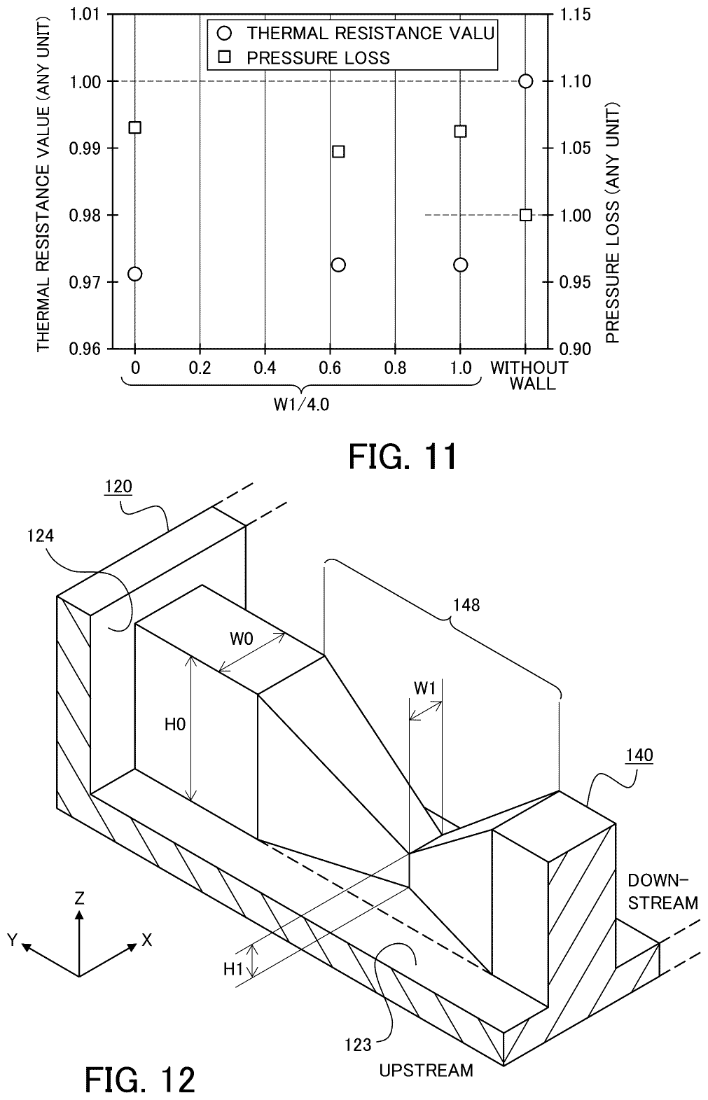

FIG. 10 is a partial plan view illustrating a shape of a wall portion in a cooler according to a second embodiment. FIG. 11 is a graph illustrating a relationship between a length of a notched section of a wall portion and cooling performance. In the graph of FIG. 11, a thermal resistance value on the left vertical axis and a pressure loss on the right vertical axis can be relative values to a thermal resistance value and a pressure loss in a cooler in which the wall portion 140 described above is not provided.

As illustrated in FIG. 10, the wall portion 140 in the cooler 1 according to the present embodiment includes a section 145 in which a thickness (dimension in the flowing direction of the refrigerant (X direction)) of the wall portion 140 indicated by a distance from a wall surface 144 facing the downstream side is W0, and a notched section 146 that varies within a range from W0 to W1 (<W0). Similar to the notched section 142 described in the first embodiment, the notched section 146 can be a section having, as both ends, substantially the same position as both ends of the semiconductor element 201 in the flow path width direction. The wall portion 140 exemplified in FIG. 10 has a constant height as viewed in the flow path width direction (Y direction), and is separated from the lower surface 102 of the top plate 100. Even when such a wall portion 140 is provided, agitation between the refrigerant having a relatively low temperature, which flows along the bottom surface 123 and collides with the wall portion 140, and the refrigerant having a relatively high temperature, which flows along the lower surface 102 of the top plate 100, and agitation between the refrigerant having a relatively low temperature, which flows along the wall surfaces 124 and 126 and collides with the wall portion 140, and the refrigerant having a relatively high temperature, which flows through a space between the protrusion portions 110, are promoted. Therefore, the temperature of the refrigerant flowing through the downstream side of the wall portion 140 is constantly maintained, and cooling performance is improved.

The graph of FIG. 11 shows a relationship between a ratio W1/4 of a minimum width W1 of the notched section to a width W0 when the width W0 of the wall portion 140 is set to 4 mm and each of the thermal resistance value and the pressure loss. In this example, the height Pz of the flow path of the refrigerant 190 is set to 5.5 mm, the height H0 of the wall portion 140 is set to 4 mm, and the positions of both ends of the wall portion 140 in the flow path width direction (Y direction) in the notched section 146 coincide with the positions of both ends of the semiconductor element 201 in the flow path width direction. The thermal resistance value and the pressure loss of “no wall portion” in the graph of FIG. 11 are the thermal resistance value and the pressure loss in the cooler in which the wall portion 140 is not provided. As illustrated in the graph of FIG. 11, the thermal resistance value is a substantially constant value smaller than that in a case without a wall portion regardless of the minimum width W1 of the notched section 146, but the pressure loss is larger than that in the case without the wall portion. In addition, when the height is constant as in the wall portion 140 of the present embodiment, stagnation is likely to occur on the upstream side of the wall portion 140 when the width ratio W1/4 is small or large. In other words, the amount of the refrigerant flowing from the upstream side to the downstream side through between the lower surface 102 of the top plate 100 and the wall portion 140 decreases. However, a difference from the pressure loss in the case where the wall portion 140 is not provided is, for example, about the same as a difference between the pressure loss in the case of H0/5.5=0 and the pressure loss in the case of 0.2≤H0/5.5≤0.9 in the graph of FIG. 8. Therefore, it is preferable that a ratio W1/W0 of the minimum width W1 to the width W0 of the wall portion 140 be within a range of 0.25≤W1/W0≤1 for the minimum width W1 of the notched section 146 of the wall portion 140 in the cooler 1 of the present embodiment. In other words, the minimum width W1 in the case of providing the notched section 146 of the wall portion 140 is preferably 25% or more of the width W0 of the wall portion 140. In the case of the wall portion 140 in which W1/W0=1, that is, the wall portion 140 in which the notched section 146 is not provided, as described above, it is preferable to determine the ratio H0/Pz of the height H0 of the wall portion 140 to the height Pz of the flow path of the refrigerant 190 such that an increase in pressure loss falls within the allowable range.

The number and shape of the notched sections 146 in the wall portion 140 in the cooler 1 of the present embodiment can be appropriately changed according to the heating element 2 disposed on the upper surface 101 of the top plate 100.

### Modification

FIG. 12 is a perspective view illustrating a modification of the shape of the notched section provided in the wall portion. The notched section of the wall portion 140 provided in the cooler 1 may have a shape including both a variation in height from the bottom surface 123 described in the first embodiment and a variation in thickness represented by a distance from the downstream-side wall surface 144 described in the second embodiment, as in a notched section 148 illustrated in FIG. 12. In the wall portion 140 exemplified in FIG. 12, since a flow path area of the notched section 148 viewed from the upstream side is wider than the wall portion 140 having a constant height described in the second embodiment, it is possible to suppress an increase in pressure loss.

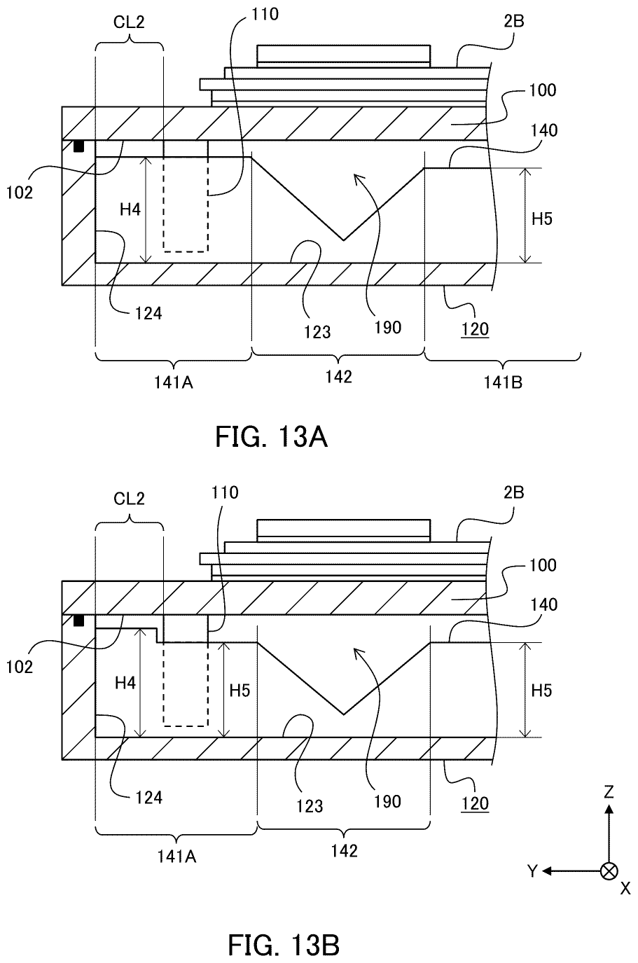

FIGS. 13A and 13B are partial cross-sectional views illustrating a modification of a height of the wall portion. FIG. 13A illustrates an example of the wall portion 140 in which the heights of two sections connected to the notched section 142 are different from each other. In the wall portion 140 of FIG. 13A, a relationship between a height H4 of a section 141A located on the positive side in the Y direction with respect to the notched section 142 (that is, located between the wall surface 124 of the water jacket 120 and the notched section 142) and a height H5 of a section 141B located on the negative side in the Y direction with respect to the notched section 142 is H4>H5. The cooler 1 having such a wall portion 140 can suppress the refrigerant flowing along the wall surface 124 and colliding with the wall portion 140 from flowing downstream through between the wall portion 140 and the top plate 100. Therefore, it is possible to more effectively perform agitation between the refrigerant having a relatively high temperature and flowing through a space between the protrusion portions 110 toward the notched section 142 and the refrigerant having a relatively low temperature and flowing along the wall surface 124. In addition, by lowering the height H5 of the section 141B away from the end in the flow path width direction (Y direction) of the wall portion 140, it is possible to suppress a decrease in flow path area and suppress an increase in pressure loss. For example, as illustrated in FIG. 13B, the wall portion 140 may vary from the height H4 to the height H5 in the section 141A located between the wall surface 124 of the water jacket 120 and the notched section 142. In this case, by setting only a portion close to the wall surface 124 to the height H4 (>H5) based on a clearance CL2 between the wall surface 124 and the protrusion portions 110, it is possible to further reduce the amount of the refrigerant that passes through between the wall portion 140 and the top plate 100 along the wall surface 124 and flows to the downstream side, and it is possible to further suppress a decrease in flow path area and suppress an increase in pressure loss.

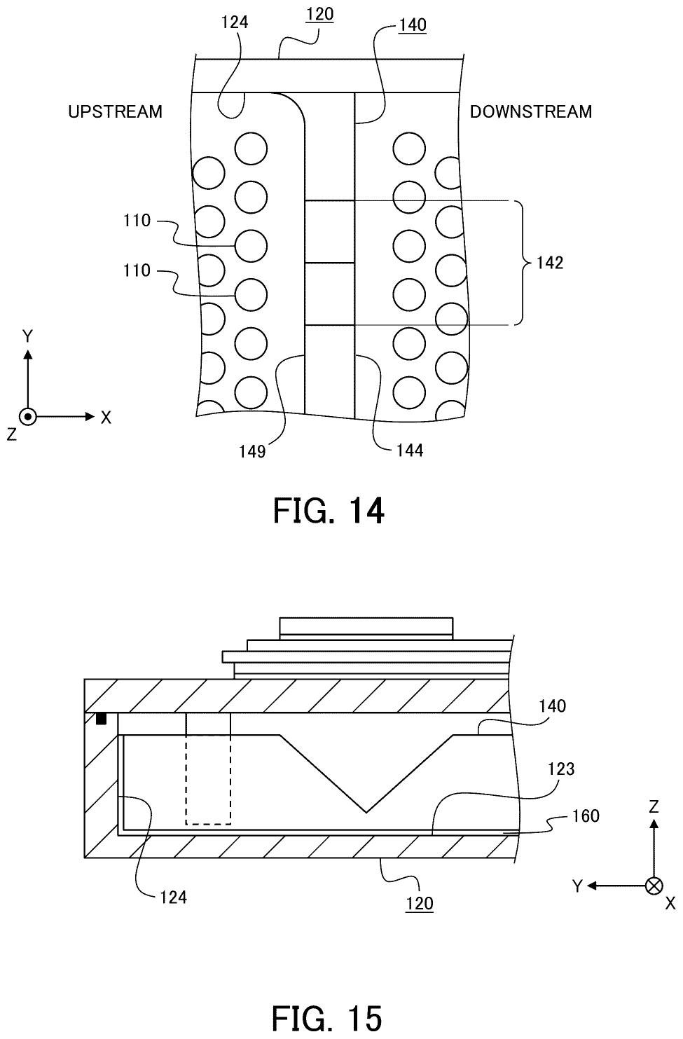

FIG. 14 is a partial plan view illustrating a modification of a shape of a wall surface on the upstream side of the wall portion. As illustrated in FIG. 14, an upstream-side wall surface 149 of the wall portion 140 may have a shape in which the shape of the end portion of the bottom surface 123 in the flow path width direction in plan view is displaced to the upstream side as approaching the wall surface 124 of the frame portion 122 of the water jacket 120. With such a shape, the refrigerant flowing along the wall surface 124 and colliding with the wall portion 140 can be easily guided in a certain direction of the notched section 142. That is, it is possible to suppress stagnation of the refrigerant at a corner portion where the wall surface 124 of the frame portion 122 and the wall surface 149 on the upstream side of the wall portion 140 are connected, and it is possible to suppress an increase in pressure loss and a decrease in cooling performance. The connection portion of the wall surface 149 with the wall surface 124 of the frame portion 122 is not limited to the curved surface shape illustrated in FIG. 14, and may be a planar shape (tapered shape) represented by a straight line.

FIG. 15 is a partial side cross-sectional view illustrating a modification of the method of providing the wall portion. The wall portion 140 of the cooler 1 described above is integrally formed with the bottom plate portion 121 as a part of the water jacket 120. However, the wall portion 140 may be formed (manufactured) separately from the bottom plate portion 121 of the water jacket 120, and may be bonded to the bottom surface 123 of the bottom plate portion 121, the wall surface 124 of the frame portion 122, and the like by a known bonding material 160.

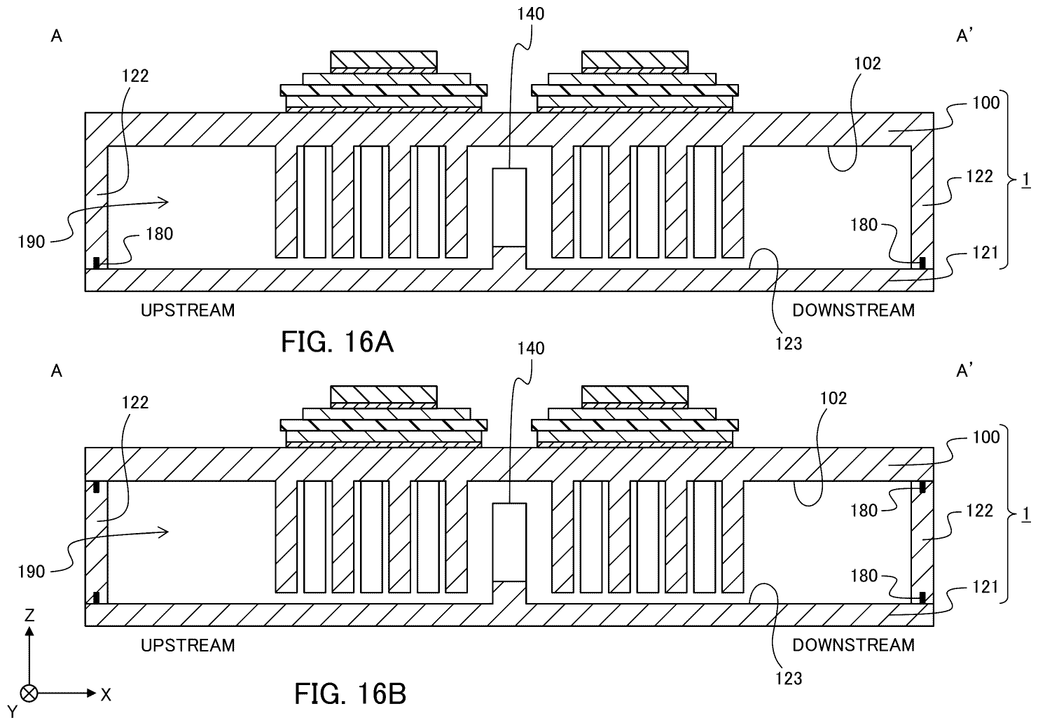

FIGS. 16A and 16B are side cross-sectional views illustrating a modification of a configuration of the cooler. In the cooler 1 described above, the water jacket 120 in which the bottom plate portion 121 and the frame portion 122 are integrally formed is attached to the top plate 100 so as to form the flow path of the refrigerant 190. However, as illustrated in FIG. 16A, in the cooler 1, the frame portion 122 may be integrally formed on the lower surface 102 of the top plate 100, and the lower surface of the frame portion 122 may be covered with the bottom plate portion 121 so as to form the flow path of the refrigerant 190. Furthermore, as illustrated in FIG. 16B, in the cooler 1, the top plate 100, the bottom plate portion 121, and the frame portion 122 may be formed as separate bodies, and the frame portion 122 may be disposed between the top plate 100 and the bottom plate portion 121 and integrated therewith so as to form the flow path of the refrigerant 190. Although not described in detail with reference to the drawings, an inlet port and an outlet port of the refrigerant in the cooler 1 are not limited to the bottom plate portion 121, and may be formed in the frame portion 122 or the top plate 100. Further, the lower surface of the plurality of protrusion portions (pin fins) 110 may be connected to the bottom surface 123 of the bottom plate portion 121 directly or via a member such as a bonding material.

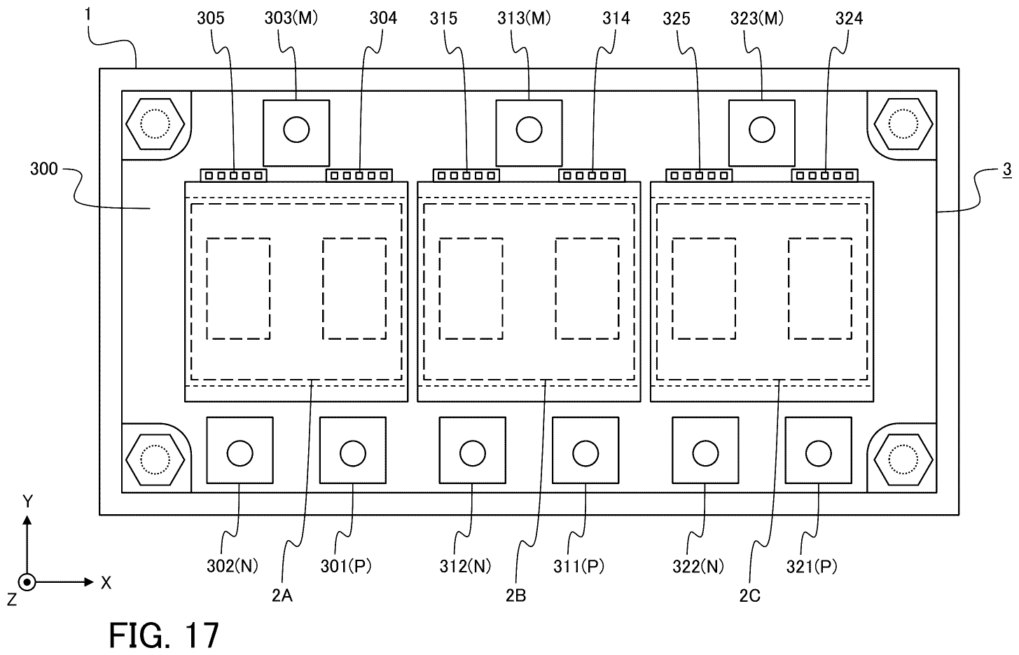

The cooler 1 described above is not applied to cooling of specific heating elements 2A and 2B, but is particularly suitable for cooling of a semiconductor element of a semiconductor module used in a power conversion device such as an inverter device. The semiconductor module may be a semiconductor module in which a dimension in the flowing direction (X direction) of the flow path of the refrigerant 190 as described below with reference to FIGS. 17 to 19 increases, but is not limited to a semiconductor module having a specific configuration.

### Application Example to Semiconductor Module

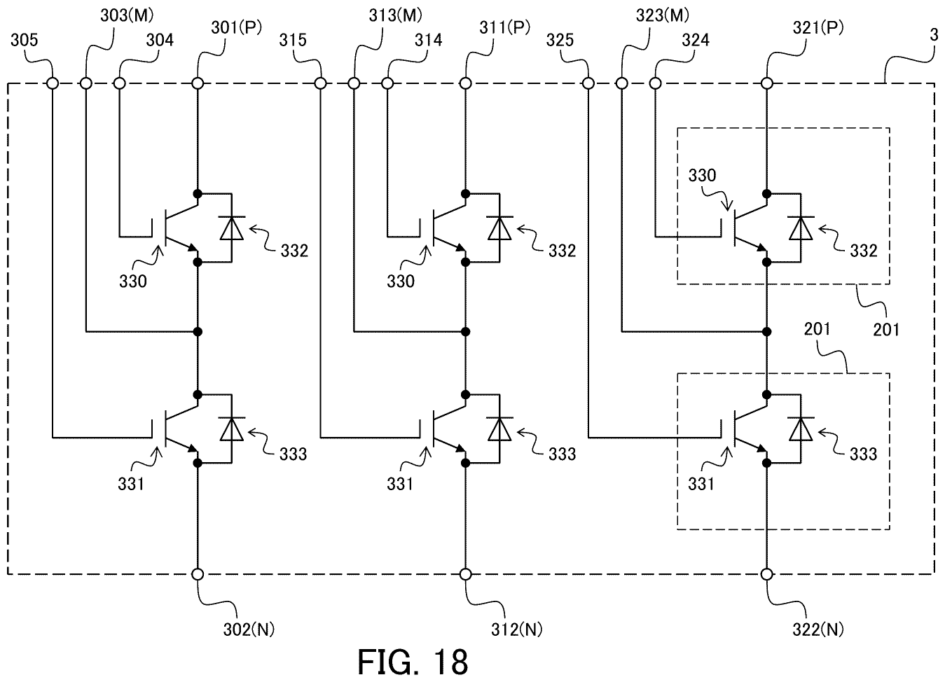

FIG. 17 is a plan view illustrating a configuration example of a semiconductor module to which the cooler according to the embodiment is attached. FIG. 18 is an equivalent circuit diagram of an exemplary power conversion circuit formed in the semiconductor module. FIG. 19 is a plan view illustrating an example of arrangement of wall portions of the cooler.

The semiconductor module 3 illustrated in FIG. 17 includes three heating elements 2A, 2B, and 2C disposed on the upper surface 101 of the top plate 100 of the cooler 1 in the longitudinal direction. Each of the heating elements 2A, 2B, and 2C includes a wiring board 200 and two semiconductor elements 201 disposed on the upper surface of the wiring board 200 (refer to FIG. 19). In the wiring board 200, conductor patterns are arranged on the upper surface and the lower surface of an insulating substrate, and the conductor pattern arranged on the lower surface of the insulating substrate is connected to be in close contact with the top plate 100 of the cooler 1 by a bonding material such as solder or a heat conducting member such as thermal grease or thermal compound. The conductor pattern disposed on the upper surface of the insulating substrate is electrically connected to an electrode of the semiconductor element 201 or a terminal of a case 300 attached to the upper surface 101 of the top plate 100. The wiring board 200 may be, for example, a Direct Copper Bonding (DCB) substrate or an Active Metal Brazing (AMB) substrate. The insulating substrate may be, for example, a ceramic substrate formed of a ceramic material such as aluminum oxide (Al₂O₃), aluminum nitride (AlN), silicon nitride (Si₃N₄), or a composite material of aluminum oxide (Al₂O₃), and zirconium oxide (ZrO₂). The insulating substrate may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like. The conductor pattern may be, for example, a metal foil such as copper or aluminum. The wiring board 200 may be referred to as a laminated substrate, an insulating circuit board, or the like. The conductor pattern may be referred to as a conductor layer, a conductive layer, or the like.

In the semiconductor module 3 illustrated in FIG. 17, for example, three power conversion circuits as illustrated in FIG. 18 are formed. The power conversion circuit includes switching elements 330 and 331 such as an insulated gate bipolar transistor (IGBT) element connected in series between a P terminal 301 and an N terminal 302 provided in the case 300, and diode elements 332 and 333 such as a free wheeling diode (FWD) element connected in anti-parallel to the IGBT element, which are formed by the wiring board 200 and the semiconductor element 201 of one heating element. The emitter of the switching element 330 of the upper arm, the collector of which is connected to the P terminal 301, and the collector of the switching clement 331 of the lower arm, the collector of which is connected to the N terminal 302, are connected to an M terminal 303 provided in the case 300. The gate of the switching element 330 of the upper arm is connected to a first control terminal 304 provided in the case 300, and the gate of the switching element 331 of the lower arm is connected to a second control terminal 305 provided in the case 300. The diode element connected in anti-parallel to the switching element may be formed in a semiconductor element different from the semiconductor element in which the switching element is formed, or may be formed in the semiconductor element in which the switching element is formed. That is, the switching element and the diode element may be formed in one semiconductor element 201. A semiconductor substrate forming the switching element and the diode element in the semiconductor element is not limited to a silicon substrate, and may be, for example, a wide band gap semiconductor substrate such as a silicon carbide (SiC) substrate and a gallium nitride (GaN) substrate. The electronic circuit formed in the semiconductor module 3 is not limited to the power conversion circuit illustrated in FIG. 17.

A cooler applied to the semiconductor module 3 illustrated in FIG. 17 includes a cooler having a lateral direction (Y direction) as a flowing direction of the refrigerant and a cooler having a longitudinal direction (X direction) as a flowing direction of the refrigerant. In the cooler having the lateral direction as the flowing direction of the refrigerant, in order to uniformly cool the three heating elements 2A, 2B, and 2C arranged in the longitudinal direction, it is necessary to provide a header portion for spreading the refrigerant flowing into the flow path of the refrigerant from an inlet port in the longitudinal direction on the upstream side of a region overlapping the heating clement in plan view. For this reason, when the lateral direction is defined as the flowing direction of the refrigerant, it is difficult to reduce the dimension of the cooler in the lateral direction. On the other hand, in the cooler 1 in which the longitudinal direction is the flowing direction of the refrigerant, as illustrated in FIG. 19, the refrigerant flowing into the flow path of the refrigerant from the inlet port can be spread in the lateral direction without providing the header portion, and the planar dimension of the cooler 1 can be easily reduced.

In addition, in a case where the wall portion 140 described above is provided in the flow path of the refrigerant in the cooler 1 in which the longitudinal direction is the flowing direction of the refrigerant, for example, as illustrated in FIG. 19, by providing the wall portion 140 between the arrangement regions of the heating elements adjacent to each other in plan view, cooling performance for the downstream heating element 2C can be brought close to cooling performance for the upstream heating element 2A. In the heating elements 2A, 2B, and 2C exemplified in FIG. 19, since the two semiconductor elements 201 are arranged in the longitudinal direction, one notched section 142 is provided in the wall portion 140.

It is noted that the semiconductor module 3 to which the cooler 1 according to the above-described embodiment is attached is not limited to one including the case 300 as illustrated in FIG. 17. The semiconductor module 3 may be, for example, a dual inline package (DIP) type semiconductor module or the like which may be referred to as a semiconductor package.

Embodiments of the cooler and the semiconductor module according to the present invention are not limited to the above-described embodiments, and may be variously changed, replaced, and modified without departing from the spirit of the technical idea. Further, when the technical idea may be implemented in another method by the progress of the technology or another derived technology, the technical idea may be carried out by using the method thereof. Therefore, the claims cover all implementations that may be included within the scope of the technical idea.

The semiconductor module of the above-described embodiments can be applied to, for example, an industrial power conversion device such as an inverter device that drives a motor of an elevator, an escalator, an air conditioning system of a building, or the like. It is noted that the application of the semiconductor module is not limited to a specific application. For example, the semiconductor module can also be applied to a power conversion device such as an inverter device that drives a motor of a vehicle such as a four-wheeled automobile, a two-wheeled vehicle, or a railway vehicle. In addition, the semiconductor module of the above-described embodiments is not limited to the inverter device, and may provide other functions.

Hereinafter, feature points in the above-described embodiments will be summarized.

A cooler according to the above-described embodiment includes: a top plate portion forming a first surface of a flow path of refrigerant; a bottom plate portion forming a second surface facing the first surface in the flow path of the refrigerant; a plurality of protrusion portions disposed in the flow path of the refrigerant, the protrusion portions protruding in a direction oriented from the first surface toward the second surface; a frame portion connecting the first surface to the second surface in the flow path of the refrigerant, the frame portion forming wall surfaces surrounding the plurality of protrusion portions; and a wall portion protruding in a direction oriented from the second surface toward the first surface, the wall portion being located between a first protrusion portion and a second protrusion portion among the plurality of protrusion portions, the first protrusion portion and the second protrusion portion being spaced apart from each other by a predetermined distance in a flowing direction of the refrigerant in the flow path of the refrigerant, in which the wall portion is respectively connected to a pair of the wall surfaces located at ends in a flow path width direction orthogonal to the flowing direction of the refrigerant in plan view of the second surface, and the wall portion has a section spaced apart from the first surface when viewed in the flow path width direction.

In the cooler according to the above-described embodiment, the wall portion is provided in a region located between a first region and a second region in the flow path of the refrigerant, the first region including the first protrusion portion and having the plurality of protrusion portions disposed therein, the second region including the second protrusion portion and having the plurality of protrusion portions disposed therein, the region not having the protrusion portion disposed therein.

In the cooler according to the above-described embodiment, the plurality of protrusion portions are spaced apart from the second surface.

In the cooler according to the above-described embodiment, the wall portion has a height varying along the second surface when viewed in the flow path width direction.

In the cooler according to the above-described embodiment, a height of the wall portion from the second surface is within a range of 20% to 90% of a height of the flow path of the refrigerant from the second surface to the first surface at a position of the wall portion.

In the cooler according to the above-described embodiment, in plan view of a third surface which is a back surface of the first surface in the top plate portion, the wall portion has a section corresponding to a heating element disposed on the third surface, the section having both ends respectively located at positions substantially identical to respective positions of both ends of the heating element in the flow path width direction, and the section having a varying height such that the height of the section is lower than a height of a section adjacent to the section.

In the cooler according to the above-described embodiment, the height of the section having the both ends respectively located at the positions substantially identical to the respective positions of the both ends of the heating element in the flow path width direction varies in a V-shape in the flow path width direction.

In the cooler according to the above-described embodiment, in the wall portion, in plan view of a third surface which is a back surface of the first surface in the top plate portion, the thickness of the section from the wall surfaces on a downstream side to the wall surfaces on an upstream side of the section is within a range of 25% to 100% of a thickness of a section adjacent to the section, the section having both ends respectively located at positions substantially identical to respective positions of both ends of the heating element in the flow path width direction disposed on the third surface.

In the cooler according to the above-described embodiment, in the wall portion, the thickness of the section having the both ends respectively located at the positions substantially identical to the respective positions of the both ends of the heating element in the flow path width direction varies so as to be smaller than the thickness of the adjacent section, and the section has a height from the second surface, the height varying so as to be lower than a height of the adjacent section.

In the cooler according to the above-described embodiment, the top plate portion has a rectangular planar shape of the first surface in plan view, and the flowing direction of the refrigerant is a longitudinal direction of the top plate portion.

A semiconductor module according to the above-described embodiment includes the cooler described above, and a wiring board and a semiconductor element disposed on a third surface of the top plate portion of the cooler, the third surface being a back surface of the first surface.

As described above, the present invention has an effect of making it possible to improve cooling performance of a cooler applied to a semiconductor module or the like, and in particular, it is useful to apply the present invention to a semiconductor module having a high calorific value during operation, such as a semiconductor module for industrial use or an electric device.

What is claimed is:

1. A cooler, comprising:
a top plate having a top plate surface and being positioned at a first side of a flow path of refrigerant that flows in the flow path in a flowing direction;
a bottom plate having a bottom plate surface facing the top plate surface and being positioned at a second side of the flow path;
a plurality of protrusions disposed on the top plate surface in the flow path, the protrusions protruding in a depth direction oriented from the first side toward the second side, the plurality of protrusions including a first protrusion and a second protrusion that are spaced apart from each other by a predetermined distance in the flowing direction;
a frame connecting the top plate surface to the bottom plate surface to surround the flow path, the frame having wall surfaces surrounding the plurality of protrusions; and
a wall disposed on the bottom plate surface and protruding in the depth direction, the wall being located in the flow path, between the first protrusion and the second protrusion, wherein the wall is respectively connected to a pair of the wall surfaces at opposite ends thereof in a width direction of the flow path that is orthogonal to the flowing direction, and has a first section that is a part of the wall, the wall, including the first section, being spaced apart from the top plate surface.

2. The cooler according to claim 1, wherein the wall is provided in a region located between a first region and a second region of the flow path and being free of the plurality of protrusions, some of the plurality of protrusions, including the first protrusion, being disposed in the first region, the rest of the plurality of protrusions, including the second protrusion, being disposed in the second region.

3. The cooler according to claim 1, wherein the plurality of protrusions are spaced apart from the bottom plate surface.

4. The cooler according to claim 1, wherein a height of the wall from the bottom plate surface in the depth direction is within a range of 20% to 90% of a distance between the bottom plate surface and the top plate surface at a position of the wall.

5. The cooler according to claim 1, wherein the wall has a height in the depth direction that varies in the width direction.

6. The cooler according to claim 5, further comprising a heat element disposed on a surface of the top plate opposite to the top plate surface, wherein
in a plan view of the top plate, the first section has opposite ends in the width direction respectively located at positions substantially identical to respective positions of opposite ends of the heating element,
the wall further has a second section adjacent in the width direction to the first section, and
the height of the first section in the depth direction varies in the width direction and is lower than a height of the second section.

7. The cooler according to claim 6, wherein the height of the first section in the depth direction varies in the width direction so that the first section forms a V-shape in a view in the flowing path direction.

8. The cooler according to claim 1, further comprising a heat element disposed on a surface of the top plate opposite to the top plate surface, wherein
in a plan view of the top plate, the first section has opposite ends in the width direction respectively located at positions substantially identical to respective positions of opposite ends of the heating element,
the wall further has a second section adjacent in the width direction to the first section, and
the first section has a range of thickness in the flowing direction that is 25% to 100% of a thickness of the second section, so that the first section is recessed from an upstream side to a down stream side of the flow path in the plan view.

9. The cooler according to claim 8, wherein, in the wall,
the thickness of the first section varies in the width direction and is smaller than the thickness of the second section, and
the first section has a height from the bottom plate surface in the depth direction that varies in the width direction and is less than a height of the second section.

10. The cooler according to claim 1, wherein in a plan view of the top plate, the top plate surface has a rectangular planar shape, and the flowing direction is a longitudinal direction of the top plate.

11. A semiconductor module comprising:
the cooler according to claim 1; and
a wiring board and a semiconductor element disposed on a bottom surface of the top plate, that is opposite to the top plate surface.
